(19) United States
(12) Patent Application Publication
(10) Pub. No.: US 2017/0197794 A1
(43) Pub. Date: Jul. 13, 2017

(54) Travel Facility

(71) Applicant: Daifuku Co., Ltd., Osaka-shi (JP)

(72) Inventor: Kazuhiro Murao, Hinocho (JP)

(21) Appl. No.: 15/403,499

(22) Filed: Jan. 11, 2017

(30) Foreign Application Priority Data
Jan. 12, 2016 (JP) 2016-003562

(51) Int. Cl. B65G 43/00; H01L 21/677; B65G 9/00

(52) U.S. Cl. CPC B65G 43/00; B65G 9/00; H01L 21/67733; H01L 21/67706; H01L 21/6773; H01L 21/67709; H01L 21/67715; B65G 2201/0297

(57) ABSTRACT

An operation device is provided with: a coupler portion configured to be coupled to a travel member that travels within a travel space that is located above a passage space that allows an operator to pass through; and a rod-shaped portion that extends from the coupler portion to the passage space. The travel member is provided with: a brake mechanism; a coupling-target portion to which the coupler portion is coupled; and a cancellation input terminal. The operation device is provided with: a cancellation output terminal configured to be connected to the cancellation input terminal; a command receiver configured to receive a manual operation that is performed to make an instruction to output the cancellation signal; and a grip configured to be gripped by the operator. The grip and the command receiver are located within the passage space when the coupler portion is coupled to the coupling-target portion.

### CROSS-REFERENCE TO RELATED APPLICATION

This application claims priority to Japanese Patent Application No. 2016-003562 filed Jan. 12, 2016, the disclosure of which is hereby incorporated in its entirety by reference.

### BACKGROUND OF THE INVENTION

Field of the Invention

The present invention relates to a travel facility that includes a travel member that travels along a travel path that is provided above a passage space that allows an operator to pass through.

Background

JP 2002-53214A discloses a travel facility that includes: a travel member that travels along a travel path that is provided above a passage space that allows an operator to pass through; and an operation device that is provided with a coupler portion configured to be coupled to the travel member, and includes a rod-shaped portion that extends from the coupler portion to the passage space. In this travel facility, a travel member that is unable to travel due to, for example, a failure that has occurred in an actuator or a controller that controls the actuator, is moved to a position at which the travel member does not obstruct other travel members from travelling, by coupling a top end of the operation device to the travel member or bringing the top end into contact with the travel member and pushing the travel member.

Usually, such a travel member is provided with a brake mechanism that restricts the travel member from travelling unless a cancellation signal is input, so that the travel member does not unintentionally move when the actuator is not driven. Therefore, in some cases, it is difficult to move the travel member by pushing the travel member, using the operation device as described above.

JP 2006-231990A discloses technology for cancelling movement restriction that is applied by the brake mechanism, in the case of moving a travel member by using external force. Specifically, the travel member is provided with an input terminal to which a cancellation signal can be externally input. Also, an auxiliary controller that is provided with: a signal generator that is configured to generate a cancellation signal; and an output terminal that is configured to output the cancellation signal, is provided. Movement restriction applied by the brake mechanism is cancelled by the cancellation signal generated by the signal generator.

However, JP 2006-231990A discloses that the task of attaching the auxiliary controller to the travel member and the task of connecting the output terminal and the input terminal to each other are performed when the operator has climbed a ladder. The auxiliary controller as described above is used only when a failure has occurred in a travel member, in order to move the travel member. Therefore, the auxiliary controller needs to be removed after the travel member has been moved to a predetermined retreat position. For this reason, when removing the auxiliary controller, an operator needs to climb up a ladder again to perform the task of removing the auxiliary controller. In other words, when moving a travel member that is unable to travel due to a failure or the like, an operator needs to climb up a ladder to perform work at a high place, and thus work efficiency is poor.

### SUMMARY OF THE INVENTION

In light of the problem above, there is demand for a travel facility that makes it possible to efficiently move a travel member when a failure occurs in the travel member.

According to one aspect of the invention, a travel facility includes: a travel path that is provided above a passage space that allows an operator to pass through; a travel member that is driven by an actuator to travel along the travel path within a travel space that is located above the passage space; and an operation device that is provided with a coupler portion configured to be coupled to the travel member, and is provided with a rod-shaped portion that extends from the coupler portion to the passage space,

wherein the travel member is provided with:
a brake mechanism configured to restrict the travel member from moving, under a condition where a cancellation signal is not input, and to cancel the restriction, under a condition where the cancellation signal is input; and
a coupling-target portion to which the coupler portion is coupled; and a cancellation input terminal to which the cancellation signal is input,

the operation device is provided with, in addition to the coupler portion and the rod-shaped portion:
a cancellation output terminal configured to be connected to the cancellation input terminal, and to output the cancellation signal;
a command receiver configured to receive a manual operation that is performed to make an instruction to output the cancellation signal from the cancellation output terminal; and
a grip configured to be gripped by the operator,

the coupler portion and the cancellation output terminal are provided in a first region of the rod-shaped portion on a top end side of the rod-shaped portion, and

the grip and the command receiver are provided in a second region of the rod-shaped portion, the second region being located within the passage space when the coupler portion is coupled to the coupling-target portion.

The coupling-target portion and the cancellation input terminal, which are provided in the travel member that travels within the travel space located above the passage space, are located at positions that are higher than the operator. According to this configuration, the coupler portion and the cancellation output terminal of the operation device can be respectively connected to the coupling-target portion and the cancellation input terminal of the travel member located within the travel space by using the rod-shaped portion, under a condition where the grip and the command receiver of the operation device are located within the passage space. In other words, the operator can couple the coupler portion to the coupling-target portion, and connect the cancellation output terminal and the cancellation input terminal to each other, without climbing up above the passage space using a ladder, for example.

The coupler portion and the coupling-target portion are coupled to each other, and the operator can make an instruction to output the cancellation signal from the cancellation output terminal by manually operating the command receiver while staying in the passage space. The cancellation output terminal and the cancellation input terminal are connected to each other, and the cancellation signal output from the cancellation output terminal is input to the cancellation input terminal provided in the travel member. Therefore, the operator can cancel the movement restriction on the travel member, applied by the brake mechanism, while staying in the passage space. Therefore, even if the device that usually outputs the cancellation signal to the brake mechanism is unable to output the cancellation signal due to a failure that has occurred in the travel member, for example, the operator can make it easier to move the travel member by cancelling the movement restriction on the travel member, applied by the brake mechanism.

Also, the grip is located within the passage space when the coupling-target portion and the coupler portion are coupled to each other. The operator who grips the grip can move the travel member by applying external force to the travel member via the rod-shaped portion. In other words, the operator can move the travel member located above the passage space without climbing up above the passage space using a ladder or the like.

As described above, with this configuration, it is possible to provide a travel facility that makes it possible to efficiently move a travel member when a failure occurs in the travel member.

Additional features and advantages of the travel facility will become clear from the following descriptions of the embodiments described with reference to the attached drawings.

### BRIEF DESCRIPTION OF THE DRAWINGS

FIG. 1 is a partially exploded side view of an overhead travel facility.

FIG. 2 is a partially exploded front view of the overhead travel facility.

FIG. 3 is an overall plan view of the overhead travel facility.

FIG. 4 is a plan view showing a branching point.

FIG. 5 is a block diagram showing configurations for controlling a travel member and a move operation device.

FIG. 6 is an overall perspective view of the move operation device.

FIG. 7 is a diagram showing a back surface of a coupler member.

FIG. 8 is a diagram showing a front surface of the coupler member.

FIG. 9 is a diagram showing a mode in which the move operation device is used.

### DETAILED DESCRIPTION OF EMBODIMENTS

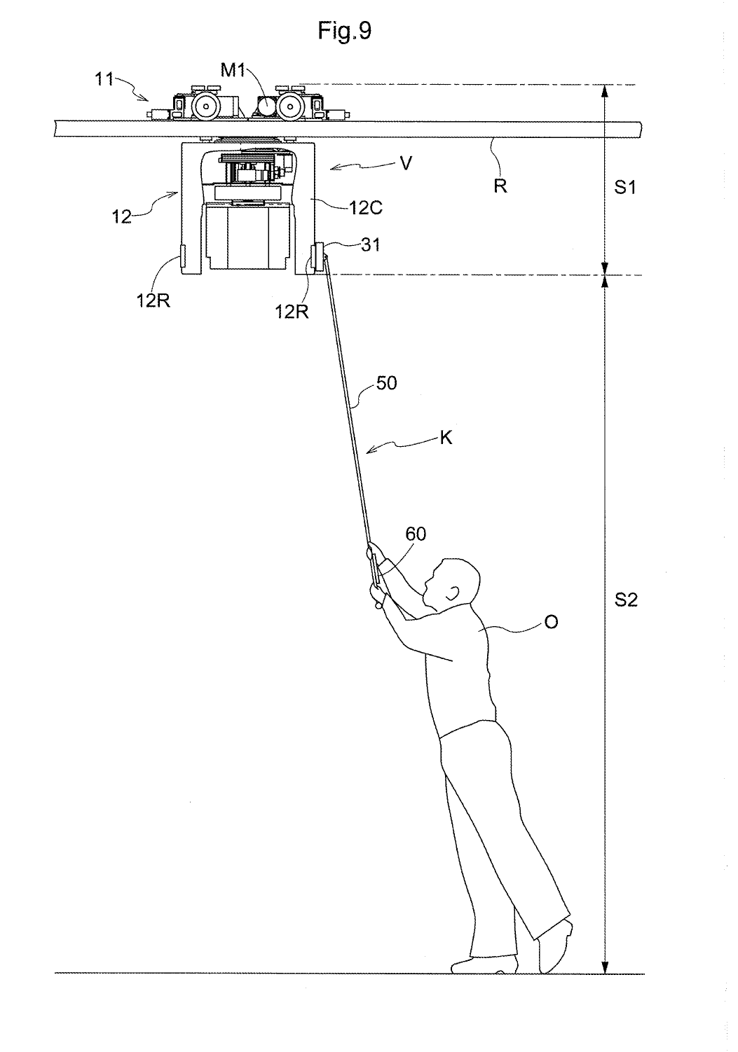

The following describes an embodiment in which a travel facility according to the present invention is applied to an overhead transport facility in a semiconductor manufacturing plant with reference to the drawings. As shown in FIG. 9, the overhead transport facility is provided with: travel rails R that are provided above a passage space S2 that allows an operator to pass through, and is suspended from a ceiling; and an overhead transport vehicle V that travels along the travel rails R within a travel space S1 that is located above the passage space S2.

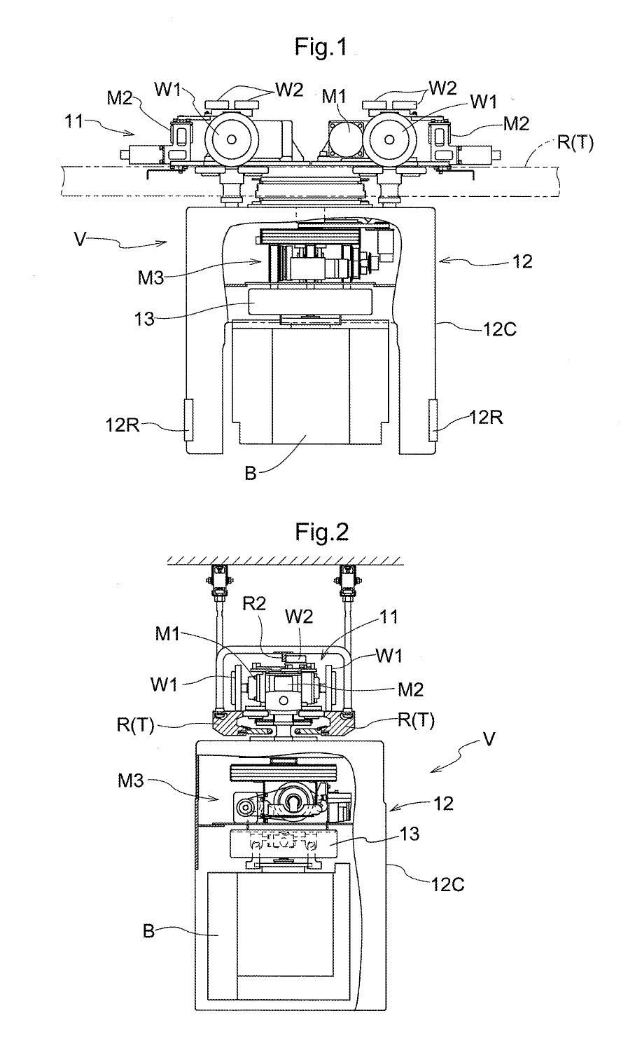

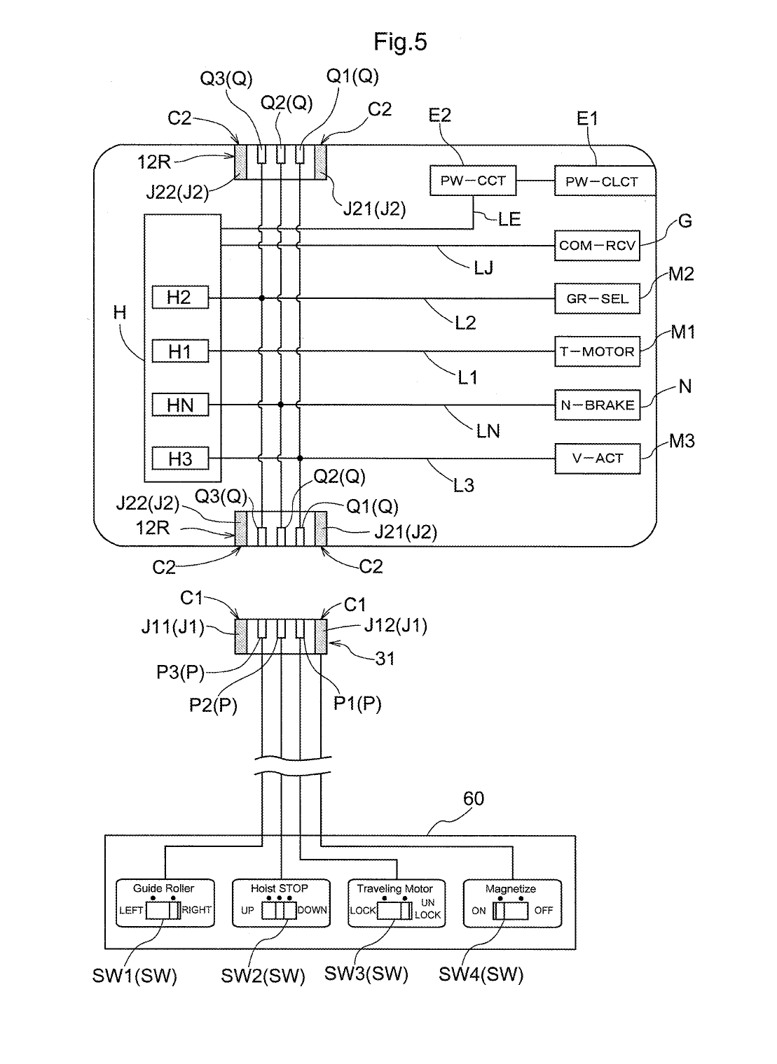

As shown in FIGS. 1 and 2, the overhead transport vehicle V is provided with: a travel portion 11 that is provided with travel wheels W1 that are configured to travel on the travel rails R; and a main body portion 12 that is suspended from and thus supported by the travel portion 11. The travel portion 11 is provided with: the travel wheels W1 that are driven to rotate along the travel rails R; and a traveling motor M1 of an electric-power driven type that drives the travel wheels W1 to rotate. Also, a transmission mechanism that is provided with a transmission shaft that transmits the rotational output of the traveling motor M1 to the travel wheels W1 is provided with a negative brake (N-BRAKE) N (see FIG. 5). The negative brake N is provided with a braking member that is biased by elastic force toward a contact position at which the negative brake N is in contact with the output shaft of the traveling motor M1. The negative brake N is also provided with an actuator that, upon electric power being input, shifts the braking member to a separation position at which the braking member is separated from the output shaft, and holds the braking member at the separation position. With such a mechanism, the braking state of the negative brake N is cancelled upon electric power being supplied thereto.

In the present embodiment, the travel rails R are equivalent to the travel path, the traveling motor M1 is equivalent to the actuator, the overhead transport vehicle V is equivalent to the travel member, the negative brake N is equivalent to the brake mechanism, and the signal that supplies electric power to cancel the braking state caused by the negative brake N is equivalent to the cancellation signal. Specifically, the travel facility (the overhead transport facility) is provided with: the travel rails R provided above the passage space S2 that allows an operator to pass through; and the overhead transport vehicle V that is driven by the traveling motor M1 to travel along the travel rails R within the travel space S1 located above the passage space S2. The overhead transport vehicle V is also provided with the negative brake N that restricts the movement of the overhead transport vehicle V under the condition where the cancellation signal is not input, and cancels the restriction under the condition where the cancellation signal is input.

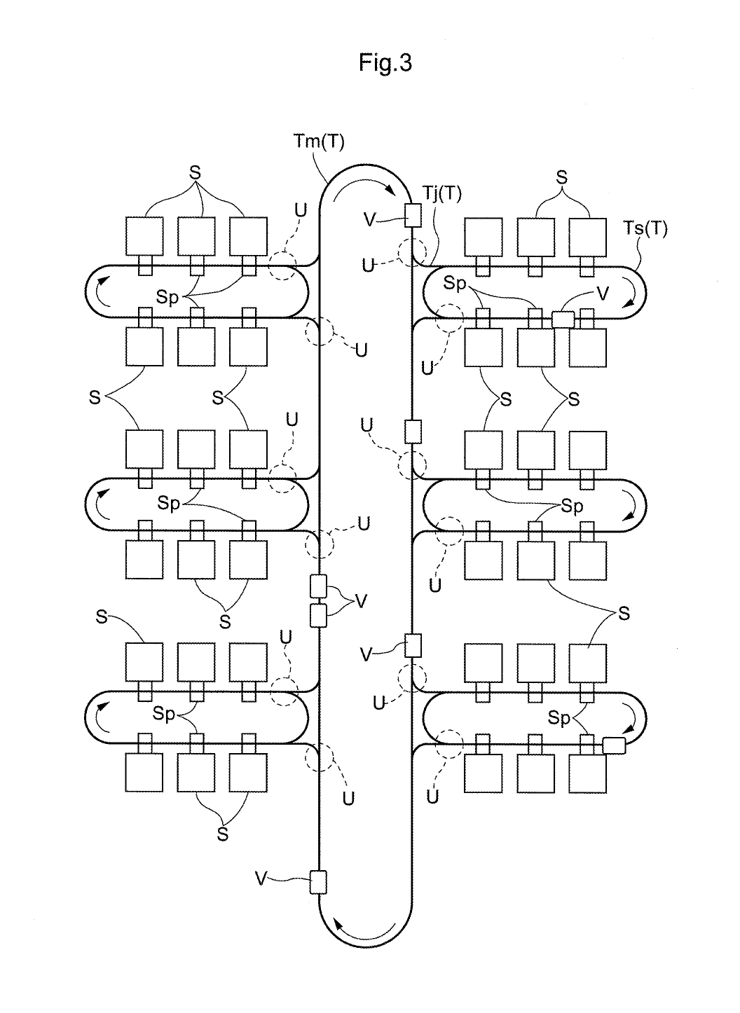

The travel portion 11 is provided with guide rollers W2 that are guided by guide rails R2 that are provided at each branching point U (see FIG. 3) of a travel path T along the travel rails R. The guide rollers W2 are configured so as to be movable in the left-right direction when seen in the direction in which the travel portion 11 travels (see FIG. 2). The guide rollers W2 are also configured to be shifted in the left-right direction, namely, to a left position and a right position, by a guide roller shifter (GR-SEL) M2 of an electric-power driven type. The guide roller shifter M2 is configured to be driven by electric power to switch the guide rollers W2 to the state of being located at a left position and the state of being located at a right position.

The travel path T along which the overhead transport vehicle V as described above travels is, as shown in FIG. 3, constituted by a ring-shaped main travel path Tm and ring-shaped sub travel paths Ts that are provided on the sides of the main travel path Tm, and the main travel path Tm and the sub travel paths Ts are connected by connection paths Tj. The direction in which the overhead transport vehicle V travels along the main travel path Tm and the sub travel paths Ts is determined to be one direction. Each of the portions surrounded by dotted lines in FIG. 3 is a branching point U from the main travel path Tm to a sub travel path Ts or a branching point U from a sub travel path Ts to the main travel path Tm.

Note that transport target articles are containers B in which a semiconductor substrate is housed, and the overhead transport vehicle V transports the containers B between transfer positions (hereinafter referred to as “the stations Sp”) of a plurality of processing devices S that are provided along the travel path T. The processing devices S are configured to perform predetermined processing on semi-finished products or the like in the course of the manufacturing of semiconductor substrates.

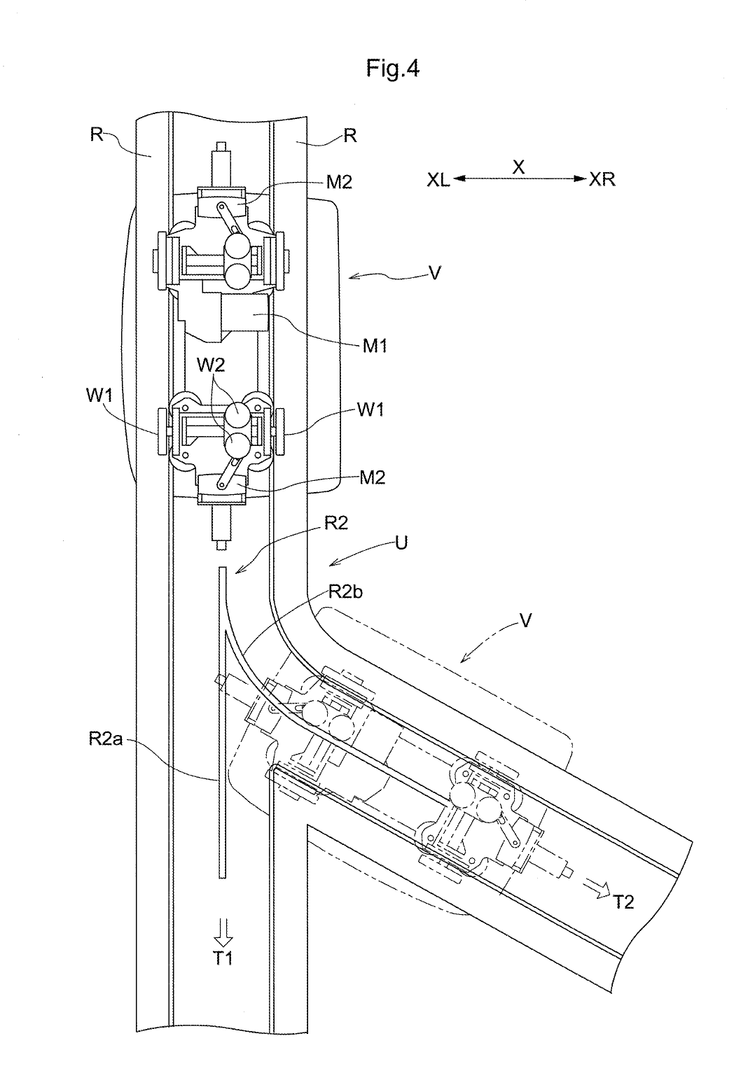

As shown in FIG. 4, at a branching point U, a guide rail R2 is provided between a pair of travel rails R in plan view. The guide rail R2 is configured to branch into a first branch guide rail R2a and a second branch guide rail R2b in correspondence with the branching of the travel path T. In FIG. 4, the overhead transport vehicle V before branching is indicated by a solid line, and the overhead transport vehicle V after branching is indicated by a two-dotted chain line.

As shown in FIG. 4, when the overhead transport vehicle V is to travel towards a travel path T2, the guide rollers W2 are shifted in the XR direction by the guide roller shifter M2. Consequently, the guide rollers W2 are brought into contact with, and are guided by, the surface of the second branch guide rail R2b on the XR side, and the overhead transport vehicle V travels along the travel path T2. On the other hand, when the overhead transport vehicle V is to travel towards a travel path T1, the guide rollers W2 are shifted in the XL direction by the guide roller shifter M2. Consequently, the guide rollers W2 are brought into contact with, and are guided by, the surface of the first branch guide rail R2a on the XL side, and the overhead transport vehicle V travels along the travel path T1.

In the present embodiment, the guide rails R2 are equivalent to a branch guide portion, the guide rollers W2 are equivalent to a guided portion, the guide roller shifter M2 is equivalent to a shifter, and electric power (a signal that supplies electric power) input to the guide roller shifter M2 is equivalent to a position shift signal. Specifically, the overhead transport vehicle V is provided with: the guide rollers W2 that are guided by the guide rails R2 provided at the branching points U of the travel rail R; and the guide roller shifter M2 that shifts the guide rollers W2 to a shift position that corresponds to a given branching direction. The guide rollers W2 are guided by the guide rails R2 so as to cause the overhead transport vehicle V to travel in a branching direction that corresponds to the shift position, and the guide roller shifter M2 is configured to shift the positions of the guide rollers W2 based on the position shift signal.

As shown in FIG. 1, the main body portion 12 is provided with a covering 12C that covers the front side and the rear side in the direction in which the travel portion 11 travels. As shown in FIG. 1, the covering 12C is formed in the shape of “C” that is open downward in side view (a view in a direction that is orthogonal to the direction in which the travel portion 11 travels, and that extends along a horizontal direction). As shown in FIGS. 1 and 2, the main body portion 12 is provided with: a vertically movable member 13 that holds a container B (which, in the present embodiment, is a container called a FOUP adapted to hold semiconductor substrates in a vertically spaced apart arrangement) and that is vertically movable, and a vertical movement actuator (V-ACT) M3 (see FIG. 5) that vertically actuates and moves the vertically movable member 13. The main body portion 12 is thus configured to travel while holding a container B to be transported with the vertically movable member 13. The vertical movement actuator M3 is driven by electric power, and is configured to switch between actuation in the direction of lifting the vertically movable member 13 and actuation in the direction of lowering the vertically movable member 13. Note that the vertically movable member 13 is provided with a grip for gripping a flange that is provided in an upper end of the FOUP that is the container B.

In the present embodiment, the container B is equivalent to an article, and electric power (a signal that supplies electric power) that drives the vertical movement actuator M3 is equivalent to a vertical movement signal. Specifically, the overhead transport vehicle V is provided with: the vertically movable member 13 that holds the container B and is vertically movable; and the vertical movement actuator M3 that vertically actuates the vertically movable member 13. The vertical movement actuator M3 is configured to lift and lower the vertically movable member 13 based on the vertical movement signal.

Next, configurations for controlling the overhead transport vehicle V will be described with reference to FIG. 5. The overhead transport vehicle V is provided with, for example: an electric power collector (PW-CLCT) E 1 that collects electric power in a non-contact fashion from a power supply rail provided along the travel rail R; a power supply circuit (PW-CCT) E2 that rectifies current and raises or lowers voltage to predetermined voltages to convert the electric power collected by the electric power collector E1 into electric power for driving each component of the overhead transport vehicle; a command receiver (COM-RCV) G that receives command information such as a transport command, transmitted by using electromagnetic waves or light; the traveling motor (T-MOTOR) M1; the guide roller shifter (GR-SEL) M2; the vertical movement actuator (V-ACT) M3; and the negative brake (N-BRAKE) N. The overhead transport vehicle V is also provided with a controller H that controls the operation of each component of the overhead transport vehicle V based on the above-described command information.

The power supply circuit E2 is electrically connected to the controller H and electric power is thus supplied to the controller H. The controller H is also provided with, for example: a control circuit that includes a microcomputer, an arithmetic unit, etc.; and an electric power control circuit that is provided with a relay for switching the state in which electric power is supplied to the traveling motor M1, the guide roller shifter M2, the vertical movement actuator M3, the negative brake N, and so on described above. The controller H and the command receiver G are connected to each other. The controller H is configured to be able to obtain operating command information from a superordinate managing device, received by the command receiver G, and to transmit information such as the results of operation of the overhead transport vehicle V, to the superordinate managing device via the command receiver G.

The controller H is provided with: a traveling motor controller H1 that controls the state in which driving electric power is supplied to the traveling motor M1; a guide roller shift controller H2 that controls the state in which driving electric power (the position shift signal) is supplied to the guide roller shifter M2; a vertical movement controller H3 that controls the state in which driving electric power (the vertical movement signal) is supplied to the vertical movement actuator M3; and a negative brake controller HN that controls the state in which electric power for releasing the negative brake N (the cancellation signal) is supplied.

The traveling motor controller H1 and the traveling motor M1 are connected to each other by a control line L1. Also, the guide roller shift controller H2 and the guide roller shifter M2 are connected to each other by a control line L2, the vertical movement controller H3 and the vertical movement actuator M3 are connected to each other by a control line L3, and the negative brake controller HN and the negative brake N are connected to each other by a control line LN.

Also, as shown in FIG. 1, the front side and the rear side of the covering 12C of the overhead transport vehicle V in the direction in which the travel portion 11 travels are each provided with a coupling-target member 12R that is provided with coupling-target portions C2 to which coupler portions C1 described below (see FIGS. 5 and 8) can be coupled. As shown in FIG. 5, the coupling-target member 12R is provided with permanent magnets J2 (a permanent magnet J22 whose magnetic pole that is closer to a coupler member 31 is one of N and S, and a permanent magnet J21 whose magnetic pole that is closer to the coupler member 31 is the other of N and 5), and the coupling-target member 12R is provided with input terminals Q to which various kinds of signals are externally input, such that a predetermined positional relationship is satisfied relative to the permanent magnets J2.

Three input terminals, namely a cancellation input terminal Q1 to which the cancellation signal can be input, an input terminal Q2 for position shift to which the position shift signal is input, and an input terminal Q3 for vertical movement to which the vertical movement signal is input are provided as the input terminals Q.

The cancellation input terminal Q1 and the control line L3 are electrically connected to each other. The input terminal Q2 for position shift and the control line LN are electrically connected to each other. The input terminal Q3 for vertical movement and the control line L2 are electrically connected to each other.

The following describes a configuration for moving the overhead transport vehicle V, along the travel rails R, to, for example, a position at which the overhead transport vehicle V does not obstruct other overhead transport vehicles V from travelling, when, for example, a failure occurs in the controller H of the above-described overhead transport vehicle V, and the negative brake N, the guide roller shifter M2, or the vertical movement actuator M3 is unable to operate (hereinafter referred to as “when a failure occurs in the overhead transport vehicle V”), with reference to FIGS. 5 to 9 as well.

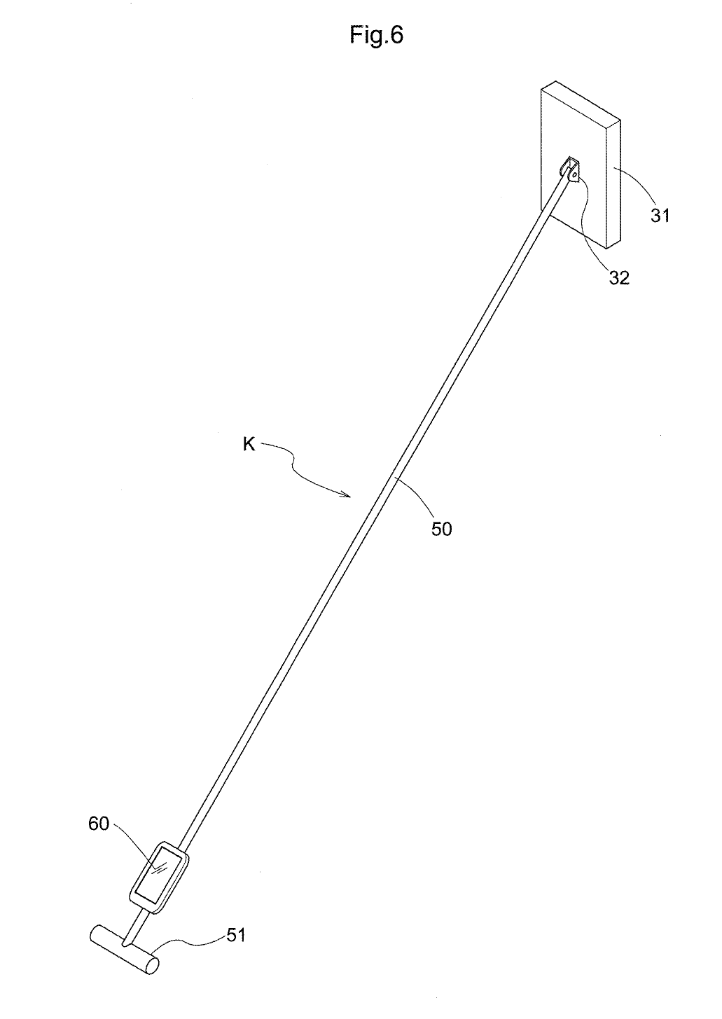

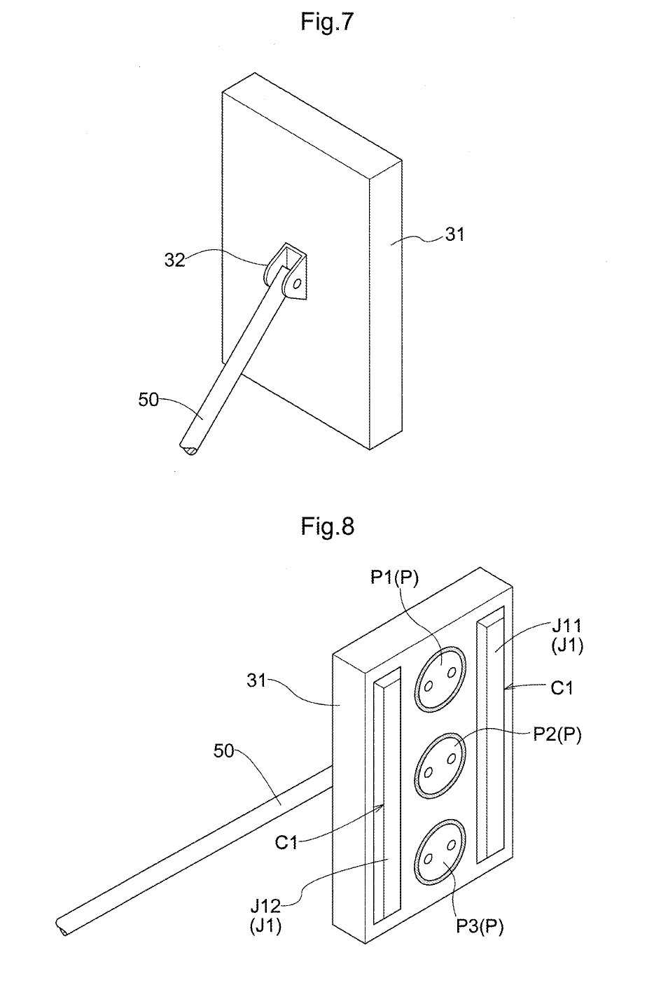

In order to move the overhead transport vehicle V in which a failure has occurred, a move operation device K shown in FIGS. 6 and 7 is used. This move operation device K is provided with: the coupler member 31 that is provided with the coupler portions C1 that are configured to be coupled to the coupling-target portions C2 of the overhead transport vehicle V; and a rod-shaped portion 50 that is connected to the coupler member 31 via a hinge 32. An end of the rod-shaped portion 50 that is opposite the coupler portions C1 is provided with a grip 51 that is configured as a T-shaped handle. In the present embodiment, the move operation device K is equivalent to the operation device.

As shown in FIG. 8, portions of the coupler member 31 that are close to the coupling-target member 12R are provided with electromagnets J1 (an electromagnet J11 whose magnetic pole that is closer to the coupling-target member 12R is one of N and S, and an electromagnet J12 whose magnetic pole that is closer to the coupling-target member 12R is the other of N and S), and the coupler member 31 is provided with output terminals P that are configured to be connected to the input terminals Q and output various kinds of signals, such that a predetermined positional relationship is satisfied relative to the electromagnets J1. As shown in FIG. 5, three output terminals, namely a cancellation output terminal P1 that outputs the cancellation signal, an output terminal P2 for position shift that outputs the position shift signal, and an output terminal P3 for vertical movement that outputs the vertical movement signal are provided as the output terminals P. It is possible to switch the electromagnets J1 to a magnetized state and a demagnetized state by switching the electromagnets J1 to the state in which electric power is supplied thereto and the state in which electric power is not supplied thereto, using a magnetize switch SW4 described below (see FIG. 5).

In the present embodiment, the portions of the coupler member 31 at which the electromagnets J1 are provided are the coupler portions C1, and the portions of the covering 12C of the overhead transport vehicle V at which the permanent magnets J2 are provided are the coupling-target portions C2. Specifically, the coupler portions C1 and the output terminals P (the cancellation output terminal P1, the output terminal P2 for position shift, and the output terminal P3 for vertical movement) are arranged so as to have a positional relationship that corresponds to the positional relationship between the coupling-target portions C2 and the input terminals Q (the cancellation input terminal Q1, the input terminal Q2 for position shift, and the input terminal Q3 for vertical movement).

Note that, as shown in FIG. 8, the coupler portions C1 may be formed as protrusions each having the shape of a truncated pyramid that is tapered toward the top of the protrusion. In contrast, the coupling-target portions C2 may be formed as recesses each having a shape that fits the shape of the corresponding coupler portion C1. With such a configuration, when the coupler portions C1 and the coupling-target portions C2 are to be coupled to each other, it is possible to accurately position the coupler portions C1 and the coupling-target portions C2 at predetermined positions.

When the coupler portions C1 and the coupling-target portions C2 are to be coupled to each other, the coupler portions C1 are guided such that the electromagnet J11 and the permanent magnet J22 attract each other and the electromagnet J12 and the permanent magnet J21 attract each other. In the present embodiment, the electromagnets J1 are equivalent to a first magnetic force generator, the permanent magnets J2 are equivalent to a second magnetic force generator, and a guide device is constituted by the electromagnets J1 and the permanent magnets J2. Specifically, the travel facility is provided with the guide device that guides the coupler portions C1 towards the coupling-target portions C2, and the guide device is provided with the electromagnets J1 that are provided in the coupler portions C1 and the permanent magnets J2 that are provided in the coupling-target portions C2 and attract, and are attracted to, the electromagnets J1. The attracting force of the electromagnets J1 and the permanent magnets J2 is set so as to be greater than the force that acts between the permanent magnets J2 and the electromagnets J1 when an operator 0 moves the overhead transport vehicle V by pulling the grip 51.

Specifically, the overhead transport vehicle V is provided with the permanent magnets J2 to which the electromagnets J1 are coupled, the cancellation input terminal Q1 to which the cancellation signal is input, the input terminal Q2 for position shift to which the position shift signal is input, and the input terminal Q3 for vertical movement to which the vertical movement signal is input. As shown in FIG. 6, the move operation device K is provided with: the cancellation output terminal P1 that is connectable to the corresponding input terminal Q and outputs the cancellation signal; a command receiver 60 that receives a manual operation that is performed to make an instruction to output the signal from the cancellation output terminal P1; and the grip 51 that is gripped by the operator 0, in addition to the coupler portions C1 and the rod-like portion 50. The command receiver 60 is provided with a power supplier (not shown) that supplies electric power corresponding to the signals output from the output terminals P.

As shown in FIG. 5, the command receiver 60 of the move operation device K is provided with: a position shift switch SW1 that receives a manual operation that is performed to make an instruction to output the position shift signal from the output terminal P2 for position shift; a vertical movement switch SW2 that receives a manual operation that is performed to make an instruction to output the vertical movement signal from the output terminal P3 for vertical movement; and a cancellation switch SW3 that receives a manual operation that is performed to make an instruction to output the cancellation signal from the cancellation output terminal P1; and the magnetize switch SW4 that receives a manual operation that switches the electromagnets J1 to the magnetized state and the demagnetized state. By using the vertical movement switch SW2, it is possible to instruct the vertically movable member 13 to move upward and downward, and to stop the upward movement and the downward movement.

The coupler portions C1 and the output terminals P (the cancellation output terminal P1, the output terminal P2 for position shift, and the output terminal P3 for vertical movement) are provided in a first region of the rod-shaped portion 50 that is on the top end side, and the grip 51 and the command receiver 60 are provided in a second region of the rod-shaped portion 50 that is located within the passage space S2 when the coupler portions C1 are coupled to the coupling-target portions C2 (see FIG. 9). In the present embodiment, when the rod-shaped portion 50 is divided into two at the center in the longitudinal direction, the region that is on the coupler member 31 side of the center is defined as the first region, and the region that is on the grip 51 side of the center is defined as the second region. Note that the sizes of the first region and the second region are not limited to the description above. For example, when the rod-shaped portion 50 is divided into n equal regions arranged in the longitudinal direction, it is possible to define the region that is closest to the coupler member 31 as the first region, and to define the region that is closest to the grip 51 as the second region. If this is the case, n may be three or more, and it is preferable that n is no less than 3 and no greater than 5.

With the above-described configuration, as shown in FIG. 9, the operator O can instruct the overhead transport vehicle V to cancel the movement restriction applied by the negative brake N, to shift the positions of the guide rollers W2, and to vertically move the vertically movable member 13 while staying in the passage space S2. Also, since it is possible to switch the electromagnets J1 to the magnetized state and the demagnetized state, when towing the overhead transport vehicle V by using the move operation device K, the electromagnets J1 and the permanent magnets J2 generate attracting force, whereas when removing the move operation device K from the overhead transport vehicle V, it is easier to remove the move operation device K from the overhead transport vehicle V.

### Other Embodiments

(1) In the description above, a configuration in which the coupler portions C1 and the output terminals P are provided in the same coupler member 31 is described as an example. However, the coupler portions C1 and the output terminals P may be separated from each other. If this is the case, it is preferable that a guide device is provided in a supporting member that supports the output terminals P, and the output terminals P are guided so as to have an appropriate positional relationship with the input terminals Q. The configuration for guiding in this case may be realized by using a magnet, or by providing a tapered surface on the overhead transport vehicle V side and guiding the supporting member that supports the output terminals P.

Also, in the description above, a configuration in which magnetic force generators (magnets) are provided in the coupler portions C1, and the coupler portions C1 and the coupling-target portions C2 are coupled to each other by attracting force generated by the magnetic force generators is described as an example. However, the coupler portions C1 and the coupling-target portions C2 may be coupled to each other by using a force other than a magnetic force. For example, a gas aspiration device may be provided in the coupler portions C1 so that negative pressure is generated in gaps between the coupler portions C1 and the coupling-target portions C2 to generate an attracting force. Alternatively, the coupler portions C1 and the coupling-target portions C2 may be physically engaged with each other by hooks and rings, for example.

(2) In the description above, an embodiment in which the move operation device K is provided with the rod-shaped portion 50 that extends along the entire length of the move operation device K is described as an example. However, the move operation device K may have a configuration in which a cord-like portion is provided on the second region side. In the configuration described above as an example, the coupler member 31 that is provided with the coupler portions C1 and the output terminals P at the top end of the rod-shaped portion 50 is provided. However, the coupler member 31 may be located at a position that is offset from the top end of the rod-shaped portion 50 to the opposite end.

(3) In the description above, an embodiment in which the overhead transport vehicle V is towed by using the move operation device K is described as an example. However, it is also possible to push the overhead transport vehicle V by using the move operation device K. It is only required that it is possible to move the overhead transport vehicle V by applying external force to the overhead transport vehicle V by using the move operation device K.

(4) In the description above, an embodiment in which the guide device is realized by using the electromagnets J1 and the permanent magnets J2 is described as an example. However, the configuration of the guide device is not limited to the above-described configuration. The guide device may guide the terminals by using a tapered surface.

(5) In the description above, an embodiment in which the coupler portions C1 are formed as protrusions each having the shape of a truncated pyramid that is tapered toward the top of the protrusion, and the coupling-target portions C2 are formed as recesses each having a shape that fits the shape of the corresponding coupler portion C1 is described as an example. However, both the coupler portions C1 and the coupling-target portions C2 may be formed in a flat shape.

(6) In the description above, an embodiment in which the first magnetic force generator is constituted by the electromagnets J1 and the second magnetic force generator is constituted by the permanent magnets J2 is described as an example. However, both the first magnetic force generator and the second magnetic force generator may be constituted by electromagnets. Also, the first magnetic force generator may be constituted by permanent magnets.

(7) In the description above, an embodiment in which the coupling-target portions C2 is provided with the permanent magnets J2 is described as an example. However, instead of the permanent magnets J2, a magnetic member made of stainless steel, iron, or the like that is attracted to the electromagnets J1 may be provided as the second magnetic force generator. If this is the case, it is preferable that a tapered surface that guides the coupler member 31 is provided on the overhead transport vehicle V side as a guide device.

(8) In the description above, a case in which the travel facility is applied to the overhead transport facility in a semiconductor manufacturing plant is described as an example. However, the travel facility may be applied to an overhead transport facility that is provided in a facility other than a semiconductor manufacturing plant. Also, in the description above, the travel facility is applied to a transport facility provided with the overhead transport vehicle V that is provided with: the travel portion 11 that travels along the travel rails R that are suspended from and supported by a ceiling; and the main body portion 12 that is suspended from and supported by the travel portion 11 and is located below the travel rails R. However, the travel facility may be applied to a facility that is provided with a travel member in which both the travel portion 11 and the main body portion 12 are located above the travel rails R.

(9) In the description above, an embodiment in which the command receiver 60 is provided with four switches, namely the position shift switch SW1, the vertical movement switch SW2, the cancellation switch SW3, and the magnetize switch SW4, is described as an example. However, it is not necessary that all of these switches are provided. For example, one or both of the position shift switch SW1 and the vertical movement switch SW2 may be omitted. Also, when the coupler portions C1 and the coupling-target portions C2 are coupled to each other by using a force other than a magnetic force, it is possible to omit the magnetize switch SW4 as a matter of course.

(10) The description above shows an example in which the attracting force of the electromagnets J1 and the permanent magnets J2 is set so as to be greater than a force that acts between the coupling-target portions C2 and the coupler portions C1 when the operator 0 moves the overhead transport vehicle V by pulling the grip 51. However, in the case where the operator O moves the overhead transport vehicle V by pushing the overhead transport vehicle V using the move operation device K, the attracting force of the electromagnets J1 and the permanent magnets J2 may be set so as to be smaller than the force that acts between the coupling-target portions C2 and the coupler portions C1 when the operator 0 moves the overhead transport vehicle V by pulling the grip 51.

(11) In the description above, an embodiment in which the grip 51 is configured as a T-shaped handle that is provided at an end of the rod-shaped portion 50 that is opposite the coupler portions C1 is described as an example. However, the grip 51 may be a grip other than the T-shaped handle. For example, a portion of the rod-shaped portion 50 may be formed in a circular or triangular ring shape that the operator O can easily grip. Alternatively, a portion of the rod-shaped portion 50 may be processed so as not to be slippery when gripped by the operator 0 and serve as the grip.

### Overview of Embodiment

The following provides a brief overview of the travel facility described above.

According to one aspect of the invention, a travel facility includes: a travel path that is provided above a passage space that allows an operator to pass through; a travel member that is driven by an actuator to travel along the travel path within a travel space that is located above the passage space; and an operation device that is provided with a coupler portion configured to be coupled to the travel member, and is provided with a rod-shaped portion that extends from the coupler portion to the passage space,

wherein the travel member is provided with:
a brake mechanism configured to restrict the travel member from moving, under a condition where a cancellation signal is not input, and to cancel the restriction, under a condition where the cancellation signal is input; and
a coupling-target portion to which the coupler portion is coupled; and a cancellation input terminal to which the cancellation signal is input,

the operation device is provided with, in addition to the coupler portion and the rod-shaped portion:
a cancellation output terminal configured to be connected to the cancellation input terminal, and to output the cancellation signal;
a command receiver configured to receive a manual operation that is performed to make an instruction to output the cancellation signal from the cancellation output terminal; and
a grip configured to be gripped by the operator,

the coupler portion and the cancellation output terminal are provided in a first region of the rod-shaped portion on a top end side of the rod-shaped portion, and

the grip and the command receiver are provided in a second region of the rod-shaped portion, the second region being located within the passage space when the coupler portion is coupled to the coupling-target portion.

The coupling-target portion and the cancellation input terminal, which are provided in the travel member that travels within the travel space located above the passage space, are located at positions that are higher than the operator. According to this configuration, the coupler portion and the cancellation output terminal of the operation device can be respectively connected to the coupling-target portion and the cancellation input terminal of the travel member located within the travel space by using the rod-shaped portion, under a condition where the grip and the command receiver of the operation device are located within the passage space. In other words, the operator can couple the coupler portion to the coupling-target portion, and connect the cancellation output terminal and the cancellation input terminal to each other, without climbing up above the passage space using a ladder, for example.

The coupler portion and the coupling-target portion are coupled to each other, and the operator can make an instruction to output the cancellation signal from the cancellation output terminal by manually operating the command receiver while staying in the passage space. The cancellation output terminal and the cancellation input terminal are connected to each other, and the cancellation signal output from the cancellation output terminal is input to the cancellation input terminal provided in the travel member. Therefore, the operator can cancel the movement restriction on the travel member, applied by the brake mechanism, while staying in the passage space. Therefore, even if the device that usually outputs the cancellation signal to the brake mechanism is unable to output the cancellation signal due to a failure that has occurred in the travel member, for example, the operator can make it easier to move the travel member by canceling the movement restriction on the travel member, applied by the brake mechanism.

Also, the grip is located within the passage space when the coupling-target portion and the coupler portion are coupled to each other. The operator who grips the grip can move the travel member by applying external force to the travel member via the rod-shaped portion. In other words, the operator can move the travel member located above the passage space without climbing up above the passage space using a ladder or the like.

As described above, with this configuration, it is possible to provide a travel facility that makes it possible to efficiently move a travel member when a failure occurs in the travel member.

Here, it is preferable that the coupler portion and the cancellation output terminal are arranged in the first region so as to have a positional relationship that corresponds to a positional relationship between the coupling target portion and the cancellation input terminal.

With this configuration, the position of the cancellation output terminal relative to the coupler portion corresponds to the position of the cancellation input terminal relative to the coupling-target portion, and it is possible to connect the cancellation output terminal and the cancellation input terminal to each other by coupling the coupler portion and the coupling-target portion to each other. Therefore, compared to the case where the operation to couple the coupler portion and the coupling-target portion to each other and the operation to connect the cancellation output terminal and the cancellation input terminal to each other are separately performed, it is possible to spare the operator some work.

It is also preferable that the travel facility further includes a guide device configured to guide the coupler portion towards the coupling-target portion.

As described above, the coupling-target portion provided in the travel member is located at a position that is higher than the operator. Therefore, it is not always easy for the operator located within the passage space to finely adjust the angle and position of the rod-shaped portion so that the coupling-target portion is appropriately located relative to the coupler portion, and to couple the coupling-target portion and the coupler portion to each other. The travel facility is provided with the guide device and the guide device guides the coupler portion towards the coupling-target portion, and thus it is possible to improve workability when the operator performs coupling work.

Here, it is preferable that the guide device is provided with: a first magnetic force generator that is provided in the coupler portion; and a second magnetic force generator that is provided in the coupling-target portion and is configured to attract, and to be attracted to, the first magnetic force generator.

With this configuration it is possible to easily guide the coupling-target portion and the coupler portion to an appropriate coupling position by utilizing the attraction effect caused by magnetic force.

Here, it is preferable that the attracting force of the first magnetic force generator and the second magnetic force generator is greater than or equal to a predetermined attracting force, and the predetermined attracting force is set to be greater than a force that acts between the coupling-target portion and the coupler portion when the operator moves the travel member by pulling the grip.

With this configuration, the operator can move the travel member by pulling the grip, using the attracting force of the first magnetic force generator and the second magnetic force generator. In other words, the first magnetic force generator and the second magnetic force generator can be used not only as a simple guide device, but also as a mechanism (means) for coupling the coupler portion and the coupling-target portion to each other. It is possible to simplify the configuration, compared to the case where the guide device and a mechanism for generating coupling force when coupling the coupler portion and the coupling-target portion to each other are separately provided.

Here, it is preferable that the first magnetic force generator has an electromagnet, and the command receiver is configured to receive a manual operation that switches the electromagnet to a magnetized state and a demagnetized state.

In other words, when the operator moves the travel member by applying external force to the travel member from the grip, the first magnetic force generator is switched to the magnetized state so as to generate an attracting force, the coupler portion is guided to the coupling-target portion, and thus coupling force can also be generated. After the travel member has been moved, the first magnetic force generator is switched to the demagnetized state so that the attracting force is reduced or eliminated, and thus it is possible to make it easier to remove the operation device from the travel member.

It is possible to switch between the magnetized state and the demagnetized state by inputting a manual operation from the command receiver that is provided in the second region. Therefore, it is unnecessary for the operator located within the passage space to climb up to a high place to perform work. In other words, this configuration makes it easier to attach/detach the operation device and the travel member to/from each other.

According to another aspect of the invention, it is preferable that the travel member is provided with: a guided portion configured to be guided by a branch guide portion that is provided at a branching point of the travel path; and a shifter configured to shift the guided portion to a shift position that corresponds to a given branching direction, the guided portion is configured to be guided by the branch guide portion so as to cause the travel member to travel in a branching direction that corresponds to the shift position, the shifter is configured to shift a position of the guided portion based on a position shift signal, the travel member is provided with a position shift input terminal to which the position shift signal is input, the operation device is provided with a position shift output terminal that is located within the first region, and is configured to be connected to the position shift input terminal, and to output the position shift signal, and the command receiver is configured to receive a manual operation that is performed to make an instruction to output the position shift signal from the position shift output terminal.

The coupler portion and the coupling-target portion are coupled to each other, and the operator can make an instruction to output the position shift signal from the position shift output terminal by manually operating the command receiver while staying in the passage space. The position shift output terminal and the position shift input terminal are connected to each other, and the position shift signal output from the position shift output terminal is input to the position shift input terminal provided in the travel member. Therefore, the operator can make an instruction to output the position shift signal by manually operating the command receiver while staying in the passage space, and shift the guided portion to the shift position that corresponds to the branching direction. Therefore, even if the device that usually outputs the position shift signal to the shifter is unable to output the position shift signal due to a failure that has occurred in the travel member, for example, the operator can move the travel member in a desired branching direction.

It is also preferable that the travel member is provided with: a vertically movable member configured to move in a vertical direction while holding an article; and a vertical movement actuator configured to actuate the vertically movable member in a vertical direction, the vertical movement actuator is configured to actuate the vertically movable member in a vertical direction based on a vertical movement signal, the travel member is provided with a vertical movement input terminal to which the vertical movement signal is input, the operation device is provided with a vertical movement output terminal that is located within the first region, and is configured to be connected to the vertical movement input terminal, and to output the vertical movement signal, and the command receiver is configured to receive a manual operation that is performed to make an instruction to output the vertical movement signal from the vertical movement output terminal.

By connecting the vertical movement output terminal and the vertical movement input terminal to each other, it is possible to input the vertical movement signal output from the vertical movement output terminal to the vertical movement input terminal provided in the travel member.

By coupling the coupler portion and the coupling-target portion to each other and inputting a manual operation to the command receiver located within the passage space, the operator can make an instruction to output the vertical movement signal, and can move the vertically movable member to a desired vertical movement position. Therefore, even if the device that usually outputs the vertical movement signal to the vertical movement actuator is unable to output the vertical movement signal due to a failure that has occurred in the travel member, for example, the operator can move the travel member to a desired vertical movement position.

What is claimed is:

1. A travel facility comprising: a travel path that is provided above a passage space that allows an operator to pass through; a travel member that is driven by an actuaotor to travel along the travel path within a travel space that is located above the passage space; and an operation device that is provided with a coupler portion configured to be coupled to the travel member, and is provided with a rod-shaped portion that extends from the coupler portion to the passage space,
wherein the travel member is provided with:
a brake mechanism configured to restrict the travel member from moving, under a condition where a cancellation signal is not input, and to cancel the restriction, under a condition where the cancellation signal is input; and
a coupling-target portion to which the coupler portion is coupled; and a cancellation input terminal to which the cancellation signal is input,
the operation device is provided with, in addition to the coupler portion and the rod-shaped portion:
a cancellation output terminal configured to be connected to the cancellation input terminal, and to output the cancellation signal;
a command receiver configured to receive a manual operation that is performed to make an instruction to output the cancellation signal from the cancellation output terminal; and
a grip configured to be gripped by the operator,
wherein the coupler portion and the cancellation output terminal are provided in a first region of the rod-shaped portion on a top end side of the rod-shaped portion, and
wherein the grip and the command receiver are provided in a second region of the rod-shaped portion, the second region being located within the passage space when the coupler portion is coupled to the coupling-target portion.

2. The travel facility according to claim 1, wherein the coupler portion and the cancellation output terminal are arranged in the first region so as to have a positional relationship that corresponds to a positional relationship between the coupling target portion and the cancellation input terminal.

3. The travel facility according to claim 1, further comprising:
a guide device configured to guide the coupler portion towards the coupling-target portion.

4. The travel facility according to claim 3, wherein the guide device is provided with: a first magnetic force generator that is provided in the coupler portion; and a second magnetic force generator that is provided in the coupling-target portion and is configured to attract, and to be attracted to, the first magnetic force generator.

5. The travel facility according to claim 4, wherein an attracting force between the first magnetic force generator and the second magnetic force generator is greater than or equal to a predetermined attracting force, and
wherein the predetermined attracting force is set to be greater than a force that acts between the coupling-target portion and the coupler portion when the operator moves the travel member by pulling the grip.

6. The travel facility according to claim 4, wherein the first magnetic force generator has an electromagnet, and
wherein the command receiver is configured to receive a manual operation that switches the electromagnet to a magnetized state and a demagnetized state.

7. The travel facility according to claim 5, wherein the first magnetic force generator has an electromagnet, and
wherein the command receiver is configured to receive a manual operation that switches the electromagnet to a magnetized state and a demagnetized state.

8. The travel facility according to claim 2, further comprising:
a guide device configured to guide the coupler portion towards the coupling-target portion.

9. The travel facility according to claim 8, wherein the guide device is provided with: a first magnetic force generator that is provided in the coupler portion; and a second magnetic force generator that is provided in the coupling-target portion and is configured to attract, and to be attracted to, the first magnetic force generator.

10. The travel facility according to claim 9, wherein an attracting force between the first magnetic force generator and the second magnetic force generator is greater than or equal to a predetermined attracting force, and
wherein the predetermined attracting force is set to be greater than a force that acts between the coupling-target portion and the coupler portion when the operator moves the travel member by pulling the grip.

11. The travel facility according to claim 9, wherein the first magnetic force generator has an electromagnet, and
wherein the command receiver is configured to receive a manual operation that switches the electromagnet to a magnetized state and a demagnetized state.

12. The travel facility according to claim 10, wherein the first magnetic force generator has an electromagnet, and
wherein the command receiver is configured to receive a manual operation that switches the electromagnet to a magnetized state and a demagnetized state.

13. The travel facility according to claim 1, wherein the travel member is provided with: a guided portion configured to be guided by a branch guide portion that is provided at a branching point of the travel path; and a shifter configured to shift the guided portion to a shift position that corresponds to a given branching direction,
the guided portion is configured to be guided by the branch guide portion so as to cause the travel member to travel in a branching direction that corresponds to the shift position,
the shifter is configured to shift a position of the guided portion based on a position shift signal,
the travel member is provided with a position shift input terminal to which the position shift signal is input,
the operation device is provided with a position shift output terminal that is located within the first region, and is configured to be connected to the position shift input terminal, and to output the position shift signal, and
the command receiver is configured to receive a manual operation that is performed to make an instruction to output the position shift signal from the position shift output terminal.

14. The travel facility according to claim 7, wherein the travel member is provided with: a guided portion configured to be guided by a branch guide portion that is provided at a branching point of the travel path; and a shifter configured to shift the guided portion to a shift position that corresponds to a given branching direction,
the guided portion is configured to be guided by the branch guide portion so as to cause the travel member to travel in a branching direction that corresponds to the shift position,
the shifter is configured to shift a position of the guided portion based on a position shift signal,
the travel member is provided with a position shift input terminal to which the position shift signal is input,
the operation device is provided with a position shift output terminal that is located within the first region, and is configured to be connected to the position shift input terminal, and to output the position shift signal, and
the command receiver is configured to receive a manual operation that is performed to make an instruction to output the position shift signal from the position shift output terminal.

15. The travel facility according to claim 12, wherein the travel member is provided with: a guided portion configured to be guided by a branch guide portion that is provided at a branching point of the travel path; and a shifter configured to shift the guided portion to a shift position that corresponds to a given branching direction,
the guided portion is configured to be guided by the branch guide portion so as to cause the travel member to travel in a branching direction that corresponds to the shift position,
the shifter is configured to shift a position of the guided portion based on a position shift signal,
the travel member is provided with a position shift input terminal to which the position shift signal is input,
the operation device is provided with a position shift output terminal that is located within the first region, and is configured to be connected to the position shift input terminal, and to output the position shift signal, and
the command receiver is configured to receive a manual operation that is performed to make an instruction to output the position shift signal from the position shift output terminal.

16. The travel facility according to claim 1, wherein the travel member is provided with: a vertically movable member configured to move in a vertical direction while holding an article; and a vertical movement actuator configured to actuate the vertically movable member in a vertical direction,
the vertical movement actuator is configured to actuate the vertically movable member in a vertical direction based on a vertical movement signal,
the travel member is provided with a vertical movement input terminal to which the vertical movement signal is input,
the operation device is provided with a vertical movement output terminal that is located within the first region, and is configured to be connected to the vertical movement input terminal, and to output the vertical movement signal, and
the command receiver is configured to receive a manual operation that is performed to make an instruction to output the vertical movement signal from the vertical movement output terminal.

17. The travel facility according to claim 7, wherein the travel member is provided with: a vertically movable member configured to move in a vertical direction while holding an article; and a vertical movement actuator configured to actuate the vertically movable member in a vertical direction,
the vertical movement actuator is configured to actuate the vertically movable member in a vertical direction based on a vertical movement signal,
the travel member is provided with a vertical movement input terminal to which the vertical movement signal is input,
the operation device is provided with a vertical movement output terminal that is located within the first region, and is configured to be connected to the vertical movement input terminal, and to output the vertical movement signal, and
the command receiver is configured to receive a manual operation that is performed to make an instruction to output the vertical movement signal from the vertical movement output terminal.

18. The travel facility according to claim 12, wherein the travel member is provided with: a vertically movable member configured to move in a vertical direction while holding an article; and a vertical movement actuator configured to actuate the vertically movable member in a vertical direction,
the vertical movement actuator is configured to actuate the vertically movable member in a vertical direction based on a vertical movement signal,
the travel member is provided with a vertical movement input terminal to which the vertical movement signal is input,
the operation device is provided with a vertical movement output terminal that is located within the first region, and is configured to be connected to the vertical movement input terminal, and to output the vertical movement signal, and
the command receiver is configured to receive a manual operation that is performed to make an instruction to output the vertical movement signal from the vertical movement output terminal.

19. The travel facility according to claim 13, wherein the travel member is provided with: a vertically movable member configured to move in a vertical direction while holding an article; and a vertical movement actuator configured to actuate the vertically movable member in a vertical direction,
the vertical movement actuator is configured to actuate the vertically movable member in a vertical direction based on a vertical movement signal,
the travel member is provided with a vertical movement input terminal to which the vertical movement signal is input,
the operation device is provided with a vertical movement output terminal that is located within the first region, and is configured to be connected to the vertical movement input terminal, and to output the vertical movement signal, and
the command receiver is configured to receive a manual operation that is performed to make an instruction to output the vertical movement signal from the vertical movement output terminal.

20. The travel facility according to claim 15, wherein the travel member is provided with: a vertically movable member configured to move in a vertical direction while holding an article; and a vertical movement actuator configured to actuate the vertically movable member in a vertical direction,
the vertical movement actuator is configured to actuate the vertically movable member in a vertical direction based on a vertical movement signal,
the travel member is provided with a vertical movement input terminal to which the vertical movement signal is input,
the operation device is provided with a vertical movement output terminal that is located within the first region, and is configured to be connected to the vertical movement input terminal, and to output the vertical movement signal, and
the command receiver is configured to receive a manual operation that is performed to make an instruction to output the vertical movement signal from the vertical movement output terminal.
